(19) United States
(12) Patent Application Publication
(10) Pub. No.: US 2009/0021158 A1
(43) Pub. Date: Jan. 22, 2009

(54) Organic electroluminescence display device

(75) Inventors: Masahiro Tanaka, Chiba (JP); Toshiyuki Matsuura, Mobara (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/219,203

(22) Filed: Jul. 17, 2008

(30) Foreign Application Priority Data
Jul. 20, 2007 (JP) 2007/188977

(51) Int. Cl. H01J 1/62

(52) U.S. Cl. 313/504

(57) ABSTRACT

An active matrix organic electroluminescence display device is provided with a transparent pixel electrode (AD1) as an anode, a pixel separation film (BNK) positioned next to and over an outer edge of the pixel electrode AD1, a transparent pixel electrode (AD2) positioned over the pixel separation film (BNK), an organic electroluminescence layer positioned over the transparent electrode (AD2), and a shared electrode (CD), functioning as a cathode, positioned over the organic electroluminescence layer. The transparent pixel electrode (AD1) is composed of indium oxide or zinc oxide; the transparent electrode (AD2) is composed of indium oxide or zinc oxide; the resistivity of the transparent electrode (AD2) is greater than the resistivity of the transparent pixel electrode (AD1); and the transparent electrode (AD2) is positioned in a layer between the organic electroluminescence layer, and the pixel separation film (BNK) and the transparent pixel electrode (AD1), covering the entire display area.

### CROSS-REFERENCE TO RELATED APPLICATION

The present application claims priority from Japanese application JP2007-188977 filed on Jul. 20, 2007, the content of which is hereby incorporated by reference into this application.

### BACKGROUND OF THE INVENTION

1. Field of the Invention

The present invention relates to a structure of an element used in an organic electroluminescence display device.

2. Description of the Related Art

A structure wherein ITO is laminated onto a surface of aluminum (Al) is known to be used in lower electrodes of top-emission (TE) organic electroluminescence display devices. Due to the high activity of the ITO surface, foreign matter readily adheres thereto, the work function changes as a result of the adherence of foreign objects, and desired levels of hole injection performance are not always obtained. In particular, lower electrodes need to be patterned for each pixel, and the adherence of foreign matter during the photolithography step is a major reason the work function is lowered.

In conventional organic electroluminescence display devices, a pixel separating film (bank) is formed on an edge of the lower electrode. The film is formed in order to prevent leak currents caused by concentrated electric fields that form on the edges of the lower electrode, and to cover contact holes that connect the lower wiring to transistors.

In the step for forming the pixel separation film as well, the surface of the lower electrode gets soiled, and the work function decreases.

Conventionally, an ITO surface having a work function of 4.6 eV (theoretical value) is subjected to an oxygen plasma treatment and ion cleaning directly so that the work function is raised to 5.3 eV (theoretical value) before the organic electroluminescence layer is vapor-deposited.

Approaches other than those involving raising the work function by cleaning have also been considered in the past.

A concept used in such alternate approaches is for a film whose work function is higher than that of ITO to be formed on the ITO.

Japanese Patent Application Laid-Open Publication Nos. 9-63771 and 2006-324537 disclose, as an example of such an approach, structures wherein a pixel electrode ITO is laminated using molybdenum oxide, ruthenium oxide, aluminum oxide, bismuth oxide, gallium oxide, germanium oxide, magnesium oxide, antimony oxide, silicon oxide, titanium oxide, tungsten oxide, yttrium oxide, zirconium oxide, iridium oxide, rhenium oxide, or vanadium oxide. The work function of these compounds is higher than that of ITO.

### SUMMARY OF THE INVENTION

The work function of the materials disclosed in Japanese Patent Application Laid-Open Publication Nos. 9-63771 and 2006-324537 is higher than that of transparent electrodes; however, the work function is excessively large. An injection barrier accordingly forms when the material is inserted between the ITO and the organic electroluminescence layer. Moreover, the material has high resistance (few carriers); therefore, carrier injection is impeded when a trap level is present due to soiling and alteration of the ITO surface.

Materials such as those disclosed in Japanese Patent Application Laid-open Publication Nos. 9-63771 and 2006-324537 are excessively resistant, and accordingly must be made thinner. However, the film thickness of the organic electroluminescent layer is a parameter of optical interference; therefore, constraints may arise in regard to the film thickness of the materials.

Using materials such as those disclosed in Japanese Patent Application Laid-open publication Nos. 9-63771 and 2006-324537, high-frequency sputtering must be used. And encountered drawbacks are that films cannot be rapidly formed, and high-quality films are difficult to obtain.

Consequently, these problems have a dramatic effect on the service life of organic electroluminescence display devices.

An object of the present invention is to provide an organic electroluminescence display device having a long service life.

(1) In order to solve the aforementioned problems, an organic electroluminescence display device associated with the present invention comprises: a transparent first conducting film; an insulating pixel separation film formed over the first conducting film; a transparent second conducting film formed over the first conducting film and the pixel separation film; an organic electroluminescence layer formed over the second conducting film; and a third conducting film formed over the organic electroluminescence layer; wherein the first conducting film is separate for each pixel; the second conducting film covers a plurality of pixels; and the second conducting film has higher resistance than the first conducting film.

(2) According to another aspect of the present invention, the first conducting film is composed of ITO.

(3) According to another aspect of the present invention, the second conducting film is composed of ITO, IZO or ZnO.

(4) In order to solve the aforementioned problems, an organic electroluminescence display device associated with the present invention comprises: a first conducting film; a pixel separation film formed over the first conducting film; a transparent second conducting film formed over the first conducting film and the pixel separation film; an organic electroluminescence layer formed over the second conducting film; and a transparent third conducting film formed over the organic electroluminescence layer; wherein the second conducting film and the third conducting film cover a plurality of pixels; and the second conducting film has higher resistance than the third conducting film.

(5) According to another aspect of the present invention, the second conducting film has an absorbance index of 1250 cm⁻¹ or less.

(6) According to another aspect of the present invention, the second conducting film has a resistivity of 100 mΩ·cm or more.

(7) According to another aspect of the present invention, the second conducting film has a thickness of 3 nm or more and 10 nm or less.

(8) According to another aspect of the present invention, the second conducting film is composed of ITO, IZO or ZnO.

(9) According to another aspect of the present invention, the third conducting film is composed of IZO or ZnO.

The organic electroluminescence display device according to the present invention comprises, for example, a pixel electrode that is an anode (corresponding to the first conducting film), a pixel separation film that covers a space between an outer edge of the pixel electrode and an adjacent pixel electrode, an anode modifying layer formed on the pixel electrode and the pixel separation film (corresponding to the second conducting film), an organic electroluminescence layer formed on the anode modifying layer, and a shared electrode formed on the organic electroluminescence layer (corresponding to the third conducting film). The pixel electrode is composed of ITO; the anode modifying layer is composed of ITO, IZO or ZnO; and the shared electrode is composed of IZO. The resistance of the ITO, IZO or ZnO constituting the anode modifying layer is set to be higher than that of the ITO, IZO or ZnO of the other layers.

According to the above configuration, a surface that is largely devoid of soiling and exhibits little difference in work function can be formed on the pixel electrode surface. This is formed from above the pixel separation film merely by sputtering a thin film provided with a higher oxygen density than that of the ITO, IZO or ZnO used in ordinary electrodes, immediately before the organic film is formed. A high level of hole injection performance can accordingly be retained.

The film of the above description preferably has a transmission factor of 1250 cm⁻¹ or less as expressed in terms of the absorbance index, a resistivity of 100 mΩ·cm or greater, and a thickness of 3 nm or more and 10 nm or less.

According to the present invention, the service life of an organic electroluminescence display device can be extended.

### BRIEF DESCRIPTION OF THE DRAWINGS

Several preferred embodiments of the present invention will be described in detail hereinafter with reference to the accompanying drawings, wherein:

FIG. 1 is a cross-section view of a TC active matrix organic electroluminescence display device of the TE variety;

FIG. 2 is a cross-section view of a TC active matrix organic electroluminescence display device of the BE variety;

FIG. 3 is a cross-section view of a TC active matrix organic electroluminescence display device of the BE variety;

FIG. 4 is a comparative view showing a difference in brightness and voltage characteristics of organic electroluminescence display devices;

FIG. 5 is a comparative view showing a difference in current efficiency for organic electroluminescence display devices; and

FIG. 6 is a comparative view showing a difference in voltage change for long periods of illumination at a temperature of 40° C. and a current density of 20 mA/cm².

### DETAILED DESCRIPTION OF THE INVENTION

Following is a description of some embodiments of the present invention.

### Embodiment 1

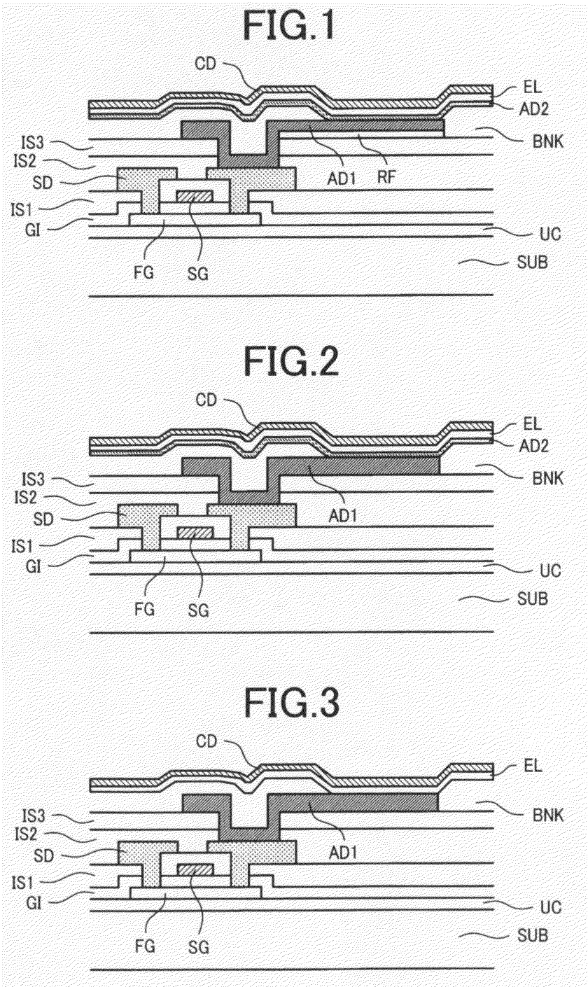

A cross-section view of a TE-type top cathode (TC) active matrix organic electroluminescence display device is shown in FIG. 1.

The following are formed in the stated order on a glass substrate SUB comprising an inorganic underlayer UC: a polysilicon semiconductor layer FG, a gate insulating film layer GI, a metal gate electrode layer SG, an inorganic interlaminar insulating film IS1, a source drain electrode layer SD, an inorganic interlaminar insulating film IS2, an inorganic interlaminar insulating film IS3, a reflecting layer RF, an anode (a pixel electrode) AD1, an anode modifying layer AD2, a pixel separation film BNK, an organic electroluminescence layer EL, and an cathode CD (shared RGB). Film-forming methods and patterning means associated with the above-listed elements are described hereunder.

The polysilicon semiconductor layer FG is obtained by using CVD to form a 50-nm (thickness) amorphous silicon film, which is then annealed by being heated with an excimer laser and thereby changed to polysilicon.

Using plasma CVD, SiO/SiN laminated films are formed to a thickness of 100 nm and 150 nm to yield the inorganic underlayer UC; a single-layer SiO film known as a TEOS film is formed to a thickness of 100 nm to yield the gate insulating film GI; a single-layer SiO film is formed to a thickness of 500 nm to yield the inorganic insulating film IS1; a single-layer SiN film is formed to a thickness of 500 nm to yield the inorganic insulating film IS2; and a three-layer SiN film is formed to a thickness of 300 nm to yield the pixel separation film BNK. A contact hole is processed with photolithography.

The organic interlaminar insulating film IS3 is made of 300-nm-thick acrylic or polyimide, and is formed in the same step as the photolithography resist step. The pixel separation film BNK is composed of an acrylic or polyimide, and is formed in the same step as the photolithography resist step.

Using sputtering, a MoW film is formed to a thickness of 110 nm to yield the metal gate electrode layer SG; a three-layer laminated film is formed from MoW, AlSi, and MoW (to thicknesses of 75 nm (MoW), 500 nm (AlSi), and 38 nm (MoW) in the stated order from the top) to yield the source drain electrode layer SD; and a two-layer Al/MoW laminated film (to thicknesses of 500 nm (Al) and 38 nm (MoW)) is formed to yield the reflecting layer RF. Photolithography is subsequently used for patterning.

The anode AD1 is a pixel electrode separated for each pixel, and is obtained by sputtering a 77-nm ITO film, processing the film using photolithography, and then performing crystallization.

The anode modifying layer AD2 and the cathode CD are overall patterned electrodes (so-called beta electrodes), and are patterned to cover all of the pixels. IZO films are formed by sputtering to a thickness of 5 nm for the anode modifying layer AD2, and to a thickness of 40 nm for the cathode CD.

A large current must not flow from the anode modifying layer AD2 to the adjacent pixels; therefore, a film of the anode modifying layer AD2 whose resistance is higher than that of the cathode CD is required. Specifically, the film must have a high resistance; i.e., a resistivity of 100 mΩ·cm or more. A film having such high resistance can be obtained using oxygen-rich IZO. When the transmittance of such a film is measured, the absorbance index is 1250 cm⁻¹ or less, meaning that the film has a transmittance higher than that of the cathode CD. Only as a guide, at a thickness of 3 nm or more, stable hole injection performance is obtained; at a thickness of 5 nm or more, some current will leak to adjacent pixels; and at thicknesses of 10 nm or more, a phenomenon that light is emitted by adjacent pixels will occur and chromatic purity will be affected. In other words, the IZO of the anode modifying layer AD2 must be within a range of 3 nm or more and 10 nm or less, and preferably 5 nm, in order to obtain matrix-drive color displays of high chromatic purity.

The organic electroluminescence layer EL is formed by laminating the following layers from the substrate in the stated order: a hole transport layer (separate RGB) HTL, an emission layer (separate RGB) EML, an electron transport layer (shared RGB) ETL, and an electron injection layer (shared RGB) EIL.

The following materials may be used for the hole transport layer HTL (separate RGB): tetraaryl benzidine compounds (triphenyl diamine: TPD), aromatic tertiary amines, hydrazone derivatives, carbazole derivatives, triazole derivatives, imidazole derivatives, oxidiazole derivatives having an amino group, polythiophene derivatives, and copper phthalocyanine derivatives.

Host materials having the ability to transport electrons and holes are jointly vapor-deposited with dopant materials that recombine electrons and holes within the host to emit fluorescent light and phosphorescent light, forming the emission layer EML (separate RGB). Metal complexes, anthracene derivatives, and carbazole derivatives preferably used as the host are tris(8-quinolinolato) aluminum, bis(8-quinolinolato) magnesium, bis(benzo(f)-8-quinolinolato) zinc, bis(2-methyl-8-quinolinolato) aluminum oxide, tris(8-quinolinolato) indium, tris(5-methyl-8-quinolinolato) aluminum, 8-quinolinolato lithium, tris(5-chloro-8-quinolinolato) gallium, bis(5-chloro-8-quinolinolato) calcium, 5,7-dichloro-8-quinolinolato aluminum, tris(5,7-dibromo-8-hydroxyquinolinolato) aluminum, and poly(zinc(II)-bis(8-hydroxy-5-quinolinyl) methane). For the dopant, it is possible to use substances that emit fluorescent light, such as bilane derivatives for red, coumarin derivatives for green, and anthracene derivatives for blue; it is also possible to use substances that emit phosphorescent light, such as iridium complexes and pyridinate derivatives.

For the electron transport layer ETL (shared RGB), it is possible to use any material having electron transporting properties. For example, it is possible to use such metal complexes as tris(8-quinolinolato) aluminum, tris(4-methyl-8-quinolinolato) aluminum, bis(2-methyl-8-quinolinolato)-4-phenylphenolate aluminum, and bis[2-[2-hydroxyphenyl]benzoxazolate]zinc; as well as 1,3-bis[5-(p-tert-butylphenyl)-1,3,4-oxadiazole-2-yl]benzene.

For the electron injection layer EIL (shared RGB), any material is acceptable as long as it has electron releasing properties in the electron transporting materials used in the electron transport layer ETL (shared RGB). Examples include alkaline metals such as lithium and cesium; alkaline earth metals such as magnesium and gallium; and rare earth metals; as well as oxides, halides and carbonates thereof.

FIG. 2 is a cross-section view of a TC active matrix organic electroluminescence display device of the bottom emission variety.

This device differs significantly from Embodiment 1 in that a reflective layer RF is not formed, and the cathode CD is formed by sputtering aluminum, instead of IZO, to a thickness of 200 nm. Moreover, the hole transport layer HTL is 40 nm thick, the emission layer EML is 40 nm thick, and the electron injection layer EIL is 20 nm thick.

### Comparative Example

FIG. 3 shows a cross-section view of a conventional TC active matrix organic electroluminescence display device of the BE variety.

Comparative Example differs significantly from Embodiment 2 in that an anode modifying layer AD2 is not formed, and the hole transport layer HTL is directly laminated over the anode AD1. In addition, the pixel electrode ITO is 70 nm thick, the hole transport layer HTL is 40 nm thick, and the emission layer EML is 40 nm thick.

### [Comparison of Results]

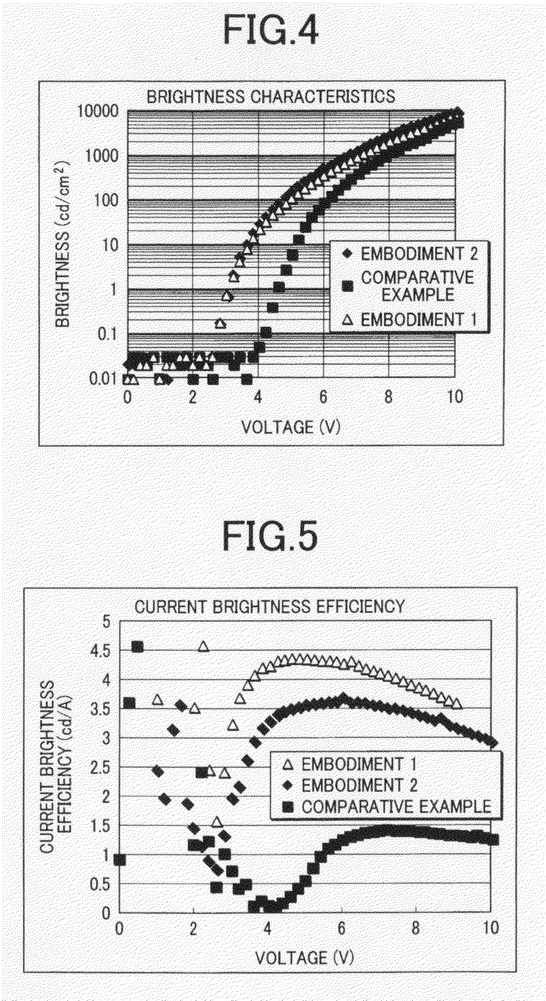

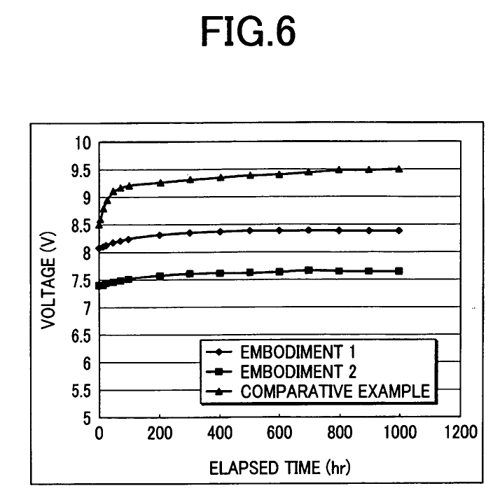

The results for each embodiment and Comparative Example are as follows. FIG. 4 shows the brightness-voltage characteristics obtained when tris(5-methyl-8-quinolinolato) aluminum is used as the electron transport material, cesium is doped at a 20% weight ratio as the electron releasing material, an aromatic tertiary amine is used as the hole transport material, a carbazole derivative is used as the emission layer host, and an iridium complex is used at an approximately 2% weight ratio as the dopant. FIG. 5 shows the current efficiency under the same conditions. FIG. 6 shows the voltage changes for a long period of illumination at a current density of 20 mA/cm² at 40° C. The effect of the present invention is evident in that there is a large voltage increase in the Comparative Example over long periods of illumination.

### [Notes]

For the anode modifying layer AD2 of the present invention, the approach used to address soiling on the surface (carrier injection interface) of the indium (ITO) and zinc (IZO) transparent conducting films used as anodes is to avoid using cleaning or polishing, and instead give just the surface a new coating that is devoid of soiling immediately after the film has been formed, thereby yielding a clean carrier injection interface. In other words, the technical concept involves a film being added; however, it is not that the capacity for increasing the work function is being imparted, but that the film is being applied only on the surface in order for the original function to be restored.

In the present invention, the anode modifying layer AD2 is formed over the entire display surface area in order to eliminate the etching patterning process, which is a source of soiling. Since forming a pixel separation film also causes soiling, the anode modifying layer AD2 of the present invention is formed over the pixel separation film BNK.

The anode modifying layer AD2 of the present invention is formed on the anode AD1 and the pixel separating film BNK over the entire display surface area; therefore, current must be prevented from flowing to adjacent pixels. Accordingly, the anode modifying layer AD2 is made more resistant than the transparent conducting film used in both the anode AD1 and the cathode CD, and is also made thinner so that its function as an electrode of the anode will be maintained (i.e., it will not function as an insulating film). The resistance can be adjusted according to the oxygen density.

While the structure of the present invention resembles that of the prior art in that a metallic nitride, SiO, or TiO₂ is used for the HIL between the anode and the organic film, the present invention differs from the prior art as described below.

(1) In the anode modifying layer AD2 of the present invention, as stated previously, a first layer is formed in advance, and, immediately before the organic film is formed, only the surface having a reduced work function is coated with a film substantially devoid of soiling immediately after being formed. In the prior art, however, a material having a large work function is introduced, with little consideration given to resistance or transmittance. The underlying concepts are different.

(2) In the prior art, the work function has been excessively large, resulting in the formation of a large injection barrier in the same way as with an organic HIL. In the present invention, however, an injection barrier formed in the anode modifying layer AD2 is small.

(3) In the prior art, the resistance has been high (few carriers are used); therefore, carrier injection has been impeded when a trap level is present due to ITO surface soiling and alteration. With IZO and ITO, which already possess carriers, no appreciable effect occurs even if carrier injection is impeded at the trap level, and no problems are presented in regard to carrier injection at the interface.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic electroluminescence display device comprising:
a transparent first conducting film;
an insulating pixel separation film formed over the first conducting film;
a transparent second conducting film formed over the first conducting film and the pixel separation film;
an organic electroluminescence layer formed over the second conducting film; and
a third conducting film formed over the organic electroluminescence layer; wherein
the first conducting film is separate for each pixel;
the second conducting film covers a plurality of pixels; and
the second conducting film has higher resistance than the first conducting film.

2. The organic electroluminescence display device of claim 1, wherein
the first conducting film is composed of ITO.

3. The organic electroluminescence display device of claim 1, wherein
the second conducting film is composed of ITO, IZO or ZnO.

4. An organic electroluminescence display device comprising:
a first conducting film;
a pixel separation film formed over the first conducting film;
a transparent second conducting film formed over the first conducting film and the pixel separation film;
an organic electroluminescence layer formed over the second conducting film; and
a transparent third conducting film formed over the organic electroluminescence layer; wherein
the second conducting film and the third conducting film cover a plurality of pixels; and
the second conducting film has higher resistance than the third conducting film.

5. The organic electroluminescence display device of claim 4, wherein
the second conducting film has an absorbance index of 1250 cm⁻¹ or less.

6. The organic electroluminescence display device of claim 4, wherein
the second conducting film has a resistivity of 100 mΩ·cm or more.

7. The organic electroluminescence display device of claim 4, wherein
the second conducting film has a thickness of 3 nm or more and 10 nm or less.

8. The organic electroluminescence display device of claim 4, wherein
the second conducting film is composed of ITO, IZO or ZnO.

9. The organic electroluminescence display device of claim 4, wherein
the third conducting film is composed of IZO or ZnO.
